(19) United States
(12) Patent Application Publication
(10) Pub. No.: US 2012/0319793 A1
(43) Pub. Date: Dec. 20, 2012

(54) OSCILLATION CIRCUIT

(75) Inventor: YOSUKE IWASA, MIYAZAKI (JP)

(73) Assignee: LAPIS SEMICONDUCTOR CO., LTD., TOKYO (JP)

(21) Appl. No.: 13/494,388

(22) Filed: Jun. 12, 2012

(30) Foreign Application Priority Data
Jun. 14, 2011 (JP) 2011-132544

(51) Int. Cl. H03L 1/00

(52) U.S. Cl. 331/176

(57) ABSTRACT

There is provided an oscillation circuit including: a band-gap circuit that outputs an output voltage adjusted for temperature dependency so as to give a constant output voltage independent of temperature; a voltage-current conversion circuit including a first variable resistor, the voltage-current conversion circuit converting an output voltage output from the band-gap circuit into an output current corresponding to the resistance of the first variable resistor and outputting a bias current based on the converted output current; and a CR oscillation circuit including a second variable resistor, a capacitor and a comparator section, the CR oscillation circuit oscillating with an oscillation frequency based on the resistance of the second variable resistor and the capacitance value of the capacitor, and the CR oscillation circuit operating according to the amperage of the bias current the comparator section has input from the voltage-current conversion circuit.

### CROSS-REFERENCE TO RELATED APPLICATION

This application is based on and claims priority under 35 USC 119 from Japanese Patent Application No. 2011-132544 filed on Jun. 14, 2011, the disclosure of which is incorporated by reference herein.

### BACKGROUND

1. Technical Field

The present invention relates to an oscillation circuit and in particular to an oscillation circuit capable of high-precision oscillation.

2. Related Art

Conventionally comparatively cheap high-precision CR (capacitor resistor) oscillation circuits are employed in place of high cost quartz oscillation circuits as oscillation circuits mounted on integrated circuits such as in Central Processing Units (CPUs) of microcomputers. CR oscillation circuits are configured, for example as shown in FIG. 7, with a resistor R3, a capacitor C1, a capacitor C2, a comparator 4, an inverter 5 and an inverter 6. The oscillation frequency of a CR oscillation circuit is determined by the values of the resistor R and the capacitors C, and is not related to the power supply voltage.

However, the resistance of a resistor R is temperature dependent and fluctuates according to temperature, resulting in the issue that the oscillation frequency also fluctuates according to temperature (namely the oscillation frequency is also temperature dependent). The temperature dependency of the resistor R changes according to manufacturing variability. It is accordingly difficult in practice to eliminate the temperature dependency of the resistor R. It is also known that the oscillation frequency fluctuates according to temperature due to factors such as the temperature dependency of internal resistance of elements other than the resistor R (the capacitors C, inverter and comparator) and temperature dependency of parasitic resistance.

There is demand for a high-precision CR oscillation circuit in which the temperature dependency of the oscillation frequency is adjusted (trimming is performed) to give a constant oscillation frequency irrespective of temperature. As a technique for trimming the temperature dependency of an oscillation frequency, there is a technique in which two types of resistors are employed with mutually differing temperature dependencies. The temperature dependency of oscillation frequency is adjusted in this method by combining a resistor having positive temperature dependency with a resistor having negative temperature dependency. However, when trimming is performed using two types of resistor, the scale of the circuit increases, and an additional mask is required for resistor fabrication, leading to new issues arising, such as an increase in integrated circuit fabrication cost.

There is a proposal for an oscillation circuit for a constant oscillation frequency independent of temperature by making current independent of temperature by canceling out the temperature dependency of a resistor using the temperature dependency of a reference voltage. As an improvement to such an oscillation circuit there is also a proposal for an oscillation circuit for a constant oscillation frequency independent of temperature even when there is a large difference in temperature dependency of resistors between each sample (large manufacturing variability) (Japanese Patent Application Laid-Open (JP-A) No. 2008-252414).

The oscillation circuit described in JP-A No. 2008-252414 includes: (1) a reference resistor for generating a reference current; (2) an integrated circuit including an operational amplifier circuit for feeding current to the reference resistor, a reference voltage generating circuit for determining a reference voltage to be applied to the reference resistor, and a constant voltage circuit for generating a constant voltage, wherein the oscillation frequency is determined in the integrated circuit based on a reference current and the constant voltage; and (3) a register for setting the temperature dependency of the reference voltage for output to the reference voltage generation circuit so as to achieve the same temperature dependency as the temperature dependency of the reference resistor.

According to the above oscillation circuit a reference current is generated according to a reference resistor provided externally to the integrated circuit. The reference voltage is added to the reference resistor by the reference voltage generation circuit. The temperature dependency of an output reference voltage of the reference voltage generation circuit is set by the register so as to have the same temperature dependency as the temperature dependency of the reference resistor. The oscillation frequency is determined by the reference current and the constant voltage that do not depend on temperature. The temperature dependency of the reference voltage can accordingly be set to match even when the temperature dependency of the reference resistor is different for each sample, enabling a stable reference current to be generated even when there is a large difference in the temperature dependency of the reference resistors for each sample.

However, in the oscillation circuit described in JP-A No. 2008-252414 a reference resistor provided externally to the integrated circuit is employed. Due to the resistance of the externally attached resistor being fixed at the design stage, the temperature dependency of the reference resistor cannot be adjusted, resulting in the issue that it is ultimately difficult to adjust the temperature dependency of the oscillation frequency. The oscillation circuit described in JP-A No. 2008-252414 also employs the method of controlling the amperage flowing from the invertor into the capacitor, and so there is the issue that it is difficult to achieve both low consumption and to reduce the temperature dependency when required. It is accordingly difficult to reduce the temperature dependency of the oscillation frequency during CPU operation when high-precision oscillation is required, and to also reduce current consumption of the oscillation circuit when in standby or halt modes when high-precision oscillation is not required.

### SUMMARY

In consideration of the above circumstances an object of the present invention is to provide an oscillation circuit that can reduce the temperature dependency of the oscillation frequency to enable high-precision oscillation when high-precision oscillation is required, and that can also reduce current consumption of the integrated circuit when high-precision oscillation is not required.

To achieve the above object, an aspect of the present invention provides an oscillation circuit including:

a band-gap circuit that outputs an output voltage adjusted for temperature dependency so as to give a constant output voltage independent of temperature;

a voltage-current conversion circuit including a first variable resistor, the voltage-current conversion circuit converting an output voltage output from the band-gap circuit into an output current corresponding to the resistance of the first variable resistor and outputting a bias current based on the converted output current; and

a CR oscillation circuit including a second variable resistor, a capacitor and a comparator section, the CR oscillation circuit oscillating with an oscillation frequency based on the resistance of the second variable resistor and the capacitance value of the capacitor, and the CR oscillation circuit operating according to the amperage of the bias current the comparator section has input from the voltage-current conversion circuit.

In the oscillation circuit of the present invention, the voltage-current conversion circuit converts the output voltage output from the band-gap circuit to an output current according to the resistance of the first variable resistor, and outputs a bias voltage based on the converted output current to the comparator section of the CR oscillation circuit. Temperature dependency is adjusted in stages by the band-gap circuit and the voltage-current conversion circuit, thereby enabling the temperature dependency of the oscillation frequency to be reduced and a constant oscillation frequency to be achieved irrespective of temperature.

The voltage-current conversion circuit also converts to an output current according to the resistance of the first variable resistor. Therefore the resistance of the first variable resistor can be set high to reduce the temperature dependency of the oscillation frequency when high-precision oscillation is required, such as during CPU operation. The resistance of the first variable resistor can also be set low to reduce current consumption when high-precision oscillation is not required, such as when in standby or halt modes.

According to the present invention, the advantageous effect is exhibited of providing an oscillation circuit that can reduce the temperature dependency of the oscillation frequency to enable high-precision oscillation when high-precision oscillation is required, and that can also reduce current consumption when high-precision oscillation is not required.

### BRIEF DESCRIPTION OF THE DRAWINGS

Exemplary embodiments of the present invention will be described in detail based on the following figures, wherein:

FIG. 1 is a circuit diagram illustrating an example of a configuration of an oscillation circuit according to an exemplary embodiment of the present invention;

FIG. 2 is a circuit diagram illustrating an example of a configuration of a band-gap circuit;

FIG. 3 is a graph illustrating the temperature dependency of output voltage of the band-gap circuit illustrated in FIG. 2;

FIG. 4 is a graph illustrating the temperature dependency of output current (bias current) of a voltage-current conversion circuit illustrated in FIG. 1;

FIG. 5A is a graph illustrating temperature dependency of oscillation frequency when a bias current of 100 nA flows;

FIG. 5B is a chart illustrating an oscillation waveform when a bias current of 100 nA flows;

FIG. 6A is a graph illustrating temperature dependency of oscillation frequency when a bias current of 10 nA flows;

FIG. 6B is a chart illustrating an oscillation waveform when a bias current of 100 nA flows; and

FIG. 7 is a circuit diagram illustrating an example of a configuration of a related CR oscillation circuit.

### DETAILED DESCRIPTION

Explanation follows regarding an exemplary embodiment of the present invention, with reference to the drawings.

CR Oscillation Circuit Configuration

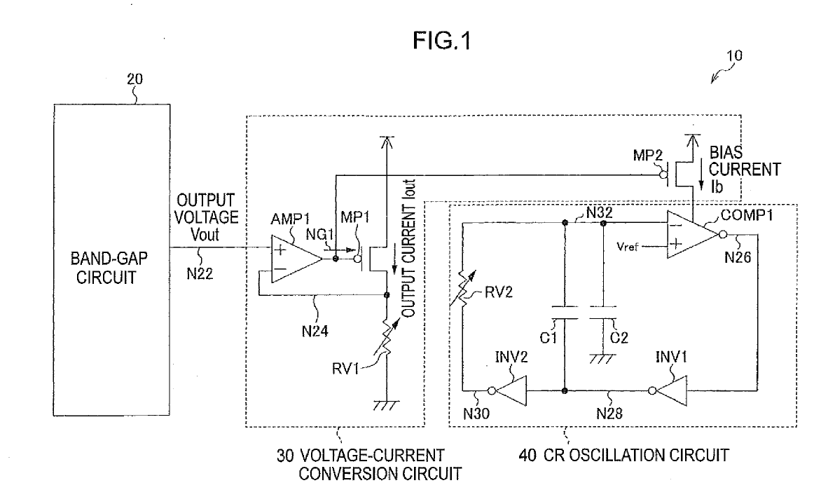

FIG. 1 is a circuit diagram illustrating an example of a configuration of an oscillation circuit according to an exemplary embodiment of the present invention. An oscillation circuit 10 is mounted on an integrated circuit, such as a CPU of a microcomputer. As shown in FIG. 1, the oscillation circuit 10 includes a band-gap circuit 20 that outputs an output voltage Vout adjusted for temperature dependency, a voltage-current conversion circuit 30 that converts the output voltage Vout of the band-gap circuit 20 to an output current Iout and outputs a bias current Ib based on the output current Tout, and a CR oscillation circuit 40 that operates according to a bias current Ib input from the voltage-current conversion circuit 30.

Generally, a band-gap circuit is a circuit for obtaining an output voltage Vout independent of temperature by adding together the electrical potential of a diode having forward bias negative temperature characteristics to a voltage proportional to absolute temperature (T). In the following a voltage proportional to absolute temperature (T) is referred to as a “Proportional To Absolute Temperature (PTAT) voltage”. It is known that the electrical potential of a diode has forward biased negative temperature characteristics, referred to as Complementary To Absolute Temperature (CTAT). An output voltage Vout can be obtained that is substantially independent of temperature by adding the PTAT voltage to the electrical potential of the diode having forward biased negative temperature characteristics (CTAT voltage). It is possible to employ a PN junction diode or an MOS diode as a diode having negative temperature characteristics.

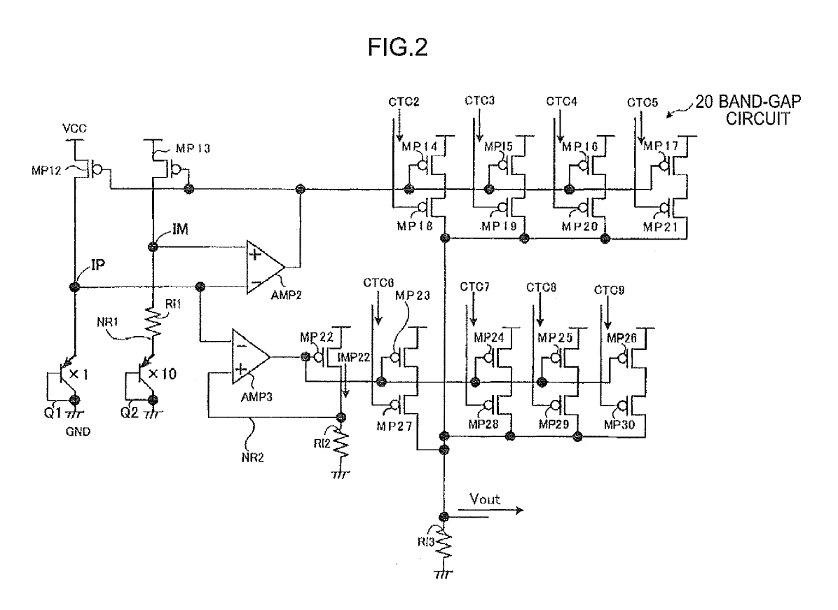

The band-gap circuit 20 generates an output voltage Vout adjusted for temperature dependency by employing the operating principles described above. The generated output voltage Vout is output from the output terminal, node N22. More details regarding the circuit configuration and operation of the band-gap circuit 20 are given later (see FIG. 2).

The voltage-current conversion circuit 30 includes an operational amplifier AMP 1, a PMOS transistor MP 1, a PMOS transistor MP 2, and a variable resistor RV1 for changing the resistance according to an input signal. The node N22 is connected to the non-inverting input terminal (+) of the operational amplifier AMP 1. A node N24 connected to the variable resistor RV1 is connected to the inverting input terminal (−) of the operational amplifier AMP 1.

The gate of the PMOS transistor MP 1 and the gate of the PMOS transistor MP 2 are connected to the output terminal of the operational amplifier AMP 1. Each of the PMOS transistor MP 1 and the PMOS transistor MP 2 are switched ON according to the electrical potential of the output NG 1 of the operational amplifier AMP 1. One end of the variable resistor RV1 is connected to the node N24 and the other end is connected to GND. The drain of the PMOS transistor MP 1 is connected to one end of the variable resistor RV1.

The operational amplifier AMP 1 performs feedback control such that the electrical potential of the node N24 connected to the variable resistor RV1 matches the output voltage Vout output from the band-gap circuit 20. When the electrical potential of the node N24 is higher than the output voltage Vout, the electrical potential of the output NG 1 of the operational amplifier AMP 1 is low, and the electrical potential of the node N24 is low. On the other hand, when the electrical potential of the node N24 is lower than the electrical potential of the output voltage Vout, the electrical potential of the output NG 1 of the operational amplifier AMP 1 is high, and the electrical potential of the node N24 is high.

The electrical potential of the node N22 connected to the non-inverting input terminal (+) of the operational amplifier AMP 1 (output voltage Vout) and the electrical potential of the node N24 connected to the inverting input terminal (−) of the operational amplifier AMP 1 are made to be substantially the same as each other by the above feedback control, thereby stabilizing the circuit. The output voltage Vout is applied to the variable resistor RV1 due to the electrical potential of the node N24 being the electrical potential of the node N22. The current (output current Iout) when the output voltage Vout is applied to the variable resistor RV1 flows in the PMOS transistor MP 1. The output voltage Vout of the band-gap circuit 20 is thereby converted into the output current Iout.

According to Ohm's law the output current Iout is a value computed by dividing the output voltage Vout by the resistance of the variable resistor RV1. Due to the variable resistor RV1 also having temperature dependency, the output current Tout therefore also fluctuates according to the temperature dependency of the variable resistor RV1. In the present exemplary embodiment the resistance of the variable resistor RV1 is changed according to the temperature dependency of the variable resistor RV1 and so the desired output current Iout can be obtained.

Generally, when there is positive temperature dependency of the output current Iout, the temperature dependency of the variable resistor RV1 is made positive (resistance increases with temperature). However, when the temperature dependency of the output current Tout is negative the temperature dependency of the variable resistor RV1 is made negative (resistance decreases with temperature). In the present exemplary embodiment the resistance of the variable resistor RV1 is adjusted such that the amperage of the output current Iout, output according to the output voltage Vout output from the band-gap circuit 20, is a specific value (for example 1.1 μA) at a specific temperature (for example 25° C.).

When a CPU requiring high-precision oscillation is operating, the resistance of the variable resistor RV1 can be set low to increase the amperage of the output current Tout. On the other hand, when high-precision is not required, such as in standby or halt modes, the current consumption of the oscillation circuit can be suppressed by setting the resistance of the variable resistor RV1 high to reduce the amperage of the output current Iout.

Preferably the variable resistor RV1 has low temperature dependency in order to reduce the variation in output current Iout. A polysilicon resistor may be employed, for example, as the variable resistor RV1. Configuration may be made with a combination of a positive temperature dependency resistor (for example a metal line) and a negative temperature dependency resistor (for example a semiconductor element).

The electrical potential of the output NG 1 of the operational amplifier AMP 1 is employed as the gate electrical potential for the PMOS transistor MP 1 and the PMOS transistor MP 2, and so the PMOS transistor MP 2 configures a current mirror circuit with the PMOS transistor MP 1. Namely, the same current as the PMOS transistor MP 1 current flows in the PMOS transistor MP 2. The output current Tout flowing in the PMOS transistor MP 1 is not dependent on temperature and so the bias current Ib flowing in the PMOS transistor MP 2 is also constant irrespective of temperature.

The CR oscillation circuit 40 is configured including a comparator COMP1, a capacitor C1, a capacitor C2, a variable resistor RV2 whose resistance varies according to input signal, an inverter INV1 and an inverter INV2. The capacitor C2 may be omitted since oscillation can be achieved without the presence of the capacitor C2. The drain of the PMOS transistor MP 2 of the voltage-current conversion circuit 30 is connected to the comparator COMP 1. The response speed of the comparator COMP1 is controlled according to the amperage of the bias current Ib fed to the comparator COMP1.

The output side node of the comparator COMP1 is denoted node N26, the output side node of the inverter INV1 is denoted node N28, the output side node of the inverter INV2 is denoted node N30 and the input side node of the inverting input terminal (−) of the comparator COMP1 is denoted node N32. One end of the capacitor C1 is connected to the node N32 and the other end is connected to the node N28. One end of the capacitor C2 is connected to the node N32 and the other end is connected to GND. One end of the variable resistor RV2 is connected to the node N30 and the other end is connected to the node N32.

The capacitor C1, the capacitor C2 and the variable resistor RV2 function as a CR oscillator unit for generating an oscillation signal with a predetermined oscillation frequency. Feedback voltage is input from the node N32 to the inverting input terminal (−) of the comparator COMP1. The constant reference voltage Vref is input to the non-inverting input terminal (+) of the comparator COMP1. A comparison amplified signal is accordingly output from the node N26 of the comparator COMP1. The inverter INV1 is input with the signal that has been output form the node N26, and the inverted signal thereof is output to the node N28. The inverter INV2 is input with the signal that has been output from the node N28, and the inverted signal thereof is output to the node N30.

The oscillation frequency of the CR oscillation circuit 40 is dependent on and varies with the temperature dependencies of the capacitor C1, the capacitor C2 and the variable resistor RV2. The temperature dependencies of the capacitor C1, the capacitor C2 and the variable resistor RV2 change according to their respective manufacturing variability. In the present exemplary embodiment the desired oscillation frequency can be obtained by varying the resistance of the variable resistor RV2 according to the temperature dependencies of the capacitor C1, the capacitor C2 and the variable resistor RV2.

The reference voltage Vref input to the comparator COMP1 may, for example, be generated by dividing the power supply voltage. Variation of the oscillation frequency due to variation in the power supply voltage can be suppressed by generating the reference voltage Vref as a divided voltage of the power supply voltage.

Band-Gap Circuit Configuration

Explanation follows regarding band-gap circuit configuration. FIG. 2 is a circuit diagram illustrating an example of a configuration of the band-gap circuit 20. The band-gap circuit 20 includes PMOS transistors MP 12 to 30, operational amplifiers AMP 2 and AMP 3, PNP transistors Q1 and Q2, and resistors R11, R12 and R13. The control signals CTC 2 to CTC 9 represent respective signals for controlling the temperature dependency of the output voltage Vout.

Explanation follows regarding operation of the band-gap circuit 20. In the band-gap circuit 20, the output voltage Vout adjusted for temperature dependency can be generated according to the principle described above. Explanation follows first regarding making the current flowing in the PMOS transistors MP 12 and MP 13 proportional to absolute temperature.

The relationship of the base-to-emitter voltage of a PNP transistor, or the forward voltage of a pn junction (referred to below as “voltage Vbe”) to absolute temperature T is known to approximate to Equation (1).

Vbe=Veg−aT (1)

Here, Veg is the band-gap voltage of silicon, about 1.2V; a is the temperature dependency of the voltage Vbe, about 2 mV/° C.; and T is the absolute temperature. The value of the temperature dependency differs according to bias current, however it is known to be about 2 mV/° C. in application ranges.

The relationship of the emitter current IE of the PNP transistor to the voltage Vbe is known to approximate to Equation (2).

IE=IO exp(qVbe/kT) (2)

Here, IE is the emitter current of the PNP transistor or the diode current; IO is a constant (proportional to surface area); q is the charge of an electron; and k is the Boltzmann constant.

If voltage gain of the operational amplifier AMP 2 is sufficiently high due to negative feedback of the operational amplifier AMP 2, the electrical potential of the node IM connected to the non-inverting input terminal of the operational amplifier AMP 2 and the electrical potential of the node IP connected to the inverting input terminal are (substantially) equivalent to each other and the circuit is stabilized.

For example, if the gate width W of the PMOS transistor MP 12 and the gate width W of the PMOS transistor MP 13 are designed to be equivalent to each other, the magnitude ratio of the current flowing in the PNP transistor Q1 to the current flowing in the PNP transistor Q2 is 1:1.

The emitter surface area of the PNP transistor Q2 is ten times the emitter surface area of the PNP transistor Q1 (the relative relationship between the emitter surface areas is indicated by “×1” and “×10” appended to PNP transistors Q1, Q2 in FIG. 2). From Equation (2), it can be seen that the base-to-emitter voltage Vbe1 of the PNP transistor Q1, and the base-to-emitter voltage Vbe2 of the PNP transistor Q2 have the relationships shown in Equation (3) and Equation (4).

I=IO exp(qVbe1/kT) Equation (3)

I=10×IO exp(qVbe2/kT) Equation (4)

Equation (5) and Equation (6) are obtained by dividing both sides and expressing Vbe1−Vbe2=ΔVbe.

10=exp(qVbe1/kT−qVbe2/kT) Equation (5)

ΔVbe=(kT/q)ln(10) Equation (6)

Namely, ΔVbe, this being the difference between the respective base-to-emitter voltages of the PNP transistor Q1 and PNP transistor Q2, is expressed by the base 10 log(ln (10)) of the current density ratio or the PNP transistor Q1 to the PNP transistor Q2 and thermal voltage (kT/q). ΔVbe here is equivalent to the potential difference between the two ends of the resistor RI1. The current ΔVbe/RI1 flows in the resistor RI1 (the resistance of the resistor RI1 is also sometimes shown as RI1).

Consequently the current IMP 12 flowing in the PMOS transistor MP 12 (and in the PMOS transistor MP 13) is expressed by Equation (7).

IMP 12=ΔVbe/RI1=(kT/q)ln(10)(1/RI1) Equation (7)

It is clear from Equation (7) and FIG. 2 that the currents flowing in the PMOS transistors MP 12 and MP 13 are currents proportional to absolute temperature.

Explanation follows regarding the decrease proportional to absolute temperature of the current flowing in the PMOS transistor MP 22. The electrical potential of the node IP connected to the inverting input terminal of an operational amplifier AMP3 and the electrical potential of the node NR2 connected to the non-inverting input terminal thereof are substantially equivalent electrical potentials to each other due to the negative feedback of the operational amplifier AMP3, stabilizing the circuit. The electrical potential of the node NR2 becomes the electrical potential of the node IP, and the base-to-emitter voltage Vbe1 of the PNP transistor Q1 is applied to the resistor RI2. The current flowing in the resistor RI2 also flows in the PMOS transistor MP 22, and so the current IMP 22 flowing in the PMOS transistor MP 22 is expressed by Equation (8) (the resistance of the resistor RI2 is also sometimes expressed as RI2).

IMP 22=Vbe1/RI2 Equation (8)

It can be seen from Equation (1) that voltage Vbe decreases proportionally to absolute temperature. Therefore it can be seen that according to Equation (8) the current flowing in the PMOS transistor NIP 22 decreases proportionally to absolute temperature.

The gate electrical potential of the PMOS transistor MP 12 is common to the gate electrical potential of the PMOS transistors MP 14 to MP 17 such that the current flowing in the PMOS transistors MP 14 to MP 17 increases proportionally to absolute temperature.

The gate electrical potential of the PMOS transistor NIP 22 is common to the gate electrical potential of the PMOS transistors NIP 23 to MP 26 such that the current flowing in the PMOS transistors MP 23 to MP 26 also decreases proportionally to absolute temperature.

Control signals CTC2 to CTC9 are respectively applied to the gates of PMOS transistors MP 18 to MP 21 and the PMOS transistors MP 27 and MP30, acting to switch ON or OFF the current of the PMOSs that act as the current source for these PMOS transistors (the PMOS transistors MP 14 to MP 17 and the PMOS transistors MP 23 to MP 26).

The drains of the PMOS transistors MP 18 to MP 21 and the PMOS transistors MP 27 to MP30 are all connected to the output terminal 22 of output voltage Vout. The currents of the PMOS transistors MP 14 to MP 17 and the PMOS transistors MP 23 to MP 26 therefore flow to the output terminal 22 of the output voltage Vout, and are converted into voltage by a resistor RI3.

Hence, by controlling the control signals CTC2 to CTC9, currents that increase proportionally to absolute temperature (PTAT currents) and the currents that decrease proportionally to absolute temperature (CTAT currents) can be added together and the proportions that are added together changed.

The output voltage Vout has positive temperature dependency when there is more current that increases proportionally to absolute temperature. The output voltage Vout has negative temperature dependency when there is less current that increases proportionally to absolute temperature. Flow of current into the output terminal of the output voltage Vout (node N22 in FIG. 1) can accordingly be controlled by making the control signals CTC2 to CTC9 “L”.

The output voltage Vout adjusted for temperature dependency according to these operating principles can be output from the output terminal. In FIG. 2, for simplification of explanation, control signals and PMOS transistors are shown for four currents that increase proportionally to absolute temperature and four currents that decrease proportionally to absolute temperature. The configuration of the circuit in FIG. 2 may however be expanded or changed so as to obtain the required adjustment precision and range.

Adjustment of Temperature Dependency of Oscillation Frequency

Explanation follows regarding operation of the oscillation circuit 10. As explained above, the band-gap circuit 20 generates the output voltage Vout adjusted for temperature dependency according to the above operating principles. The generated output voltage Vout is output from the node N22 to the voltage-current conversion circuit 30. The voltage-current conversion circuit 30 converts the output voltage Vout into the desired output current Tout by changing the resistance of the variable resistor RV1 according to the temperature dependency of the variable resistor RV1. Namely, the temperature dependency of the output current Tout is adjusted. During CPU operation, the resistance of the variable resistor RV1 can also be set low to increase the amperage of the output current Tout, and in halt mode the resistance of the variable resistor RV1 can also be set high to decrease the amperage of the output current Tout.

The voltage-current conversion circuit 30 outputs the bias current Ib that is the same as the output current Iout adjusted for temperature dependency. Since the output current Tout is not dependent on temperature, the bias current Ib is also constant irrespective of temperature. Namely, the bias current Ib adjusted for temperature dependency is input to the comparator COMP1 of the CR oscillation circuit 40. The response speed of the comparator COMP 1 is controlled according to the amperage of the bias current Ib supplied to the comparator COMP1. The CR oscillation circuit 40 oscillates at the desired oscillation frequency by changing the resistance of the variable resistor RV2 according to the temperature dependencies of the capacitor C1, the capacitor C2 and the variable resistor RV2. Namely, the temperature dependency of the oscillation frequency is adjusted.

As described above, in the present exemplary embodiment, the temperature dependency of the oscillation frequency is adjusted by adjusting the temperature dependency of the output voltage Vout in the band-gap circuit 20 and adjusting the temperature dependency of the output current Tout (the bias current Ib) with the voltage-current conversion circuit 30. In addition, the temperature dependency of the oscillation frequency is finally adjusted by the variable resistor RV2 of the CR oscillation circuit 40. A constant oscillation frequency is accordingly achieved irrespective of temperature.

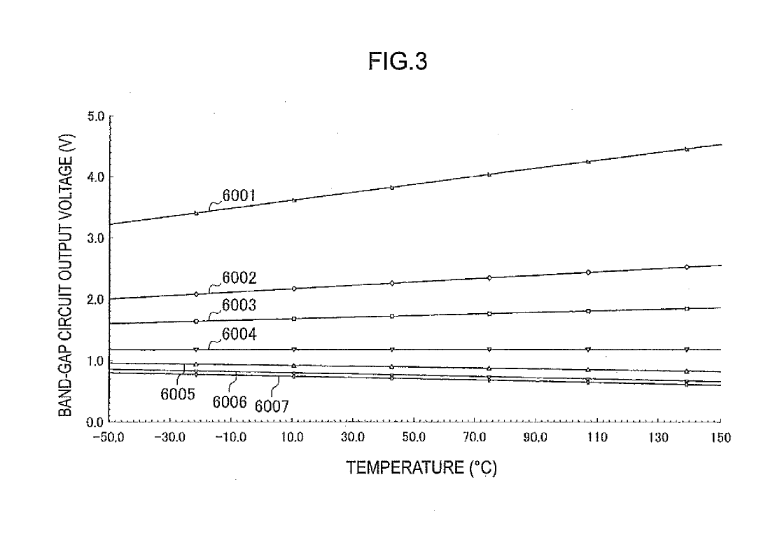

The graph in FIG. 3 illustrates the temperature dependency of the output voltage of a band-gap circuit. As illustrated in FIG. 3, the output voltage Vout output from the band-gap circuit 20 fluctuates according to temperature unless temperature dependency is adjusted. For example, the temperature dependency of the output voltage Vout changes from line 6001 to line 6007 as the resistance of the resistor RI1 of FIG. 2 gets progressively higher.

On the line 6004, the output voltage Vout is substantially constant irrespective of temperature. The temperature dependency of the output voltage Vout is accordingly adjusted to the temperature dependency shown on line 6004. For example, the resistance of the resistor RI1 is adjusted during design or sample production. Alternatively, the control signals CTC2 to CTC9 shown in FIG. 2 are controlled so as to change the resistance of the resistor RI1.

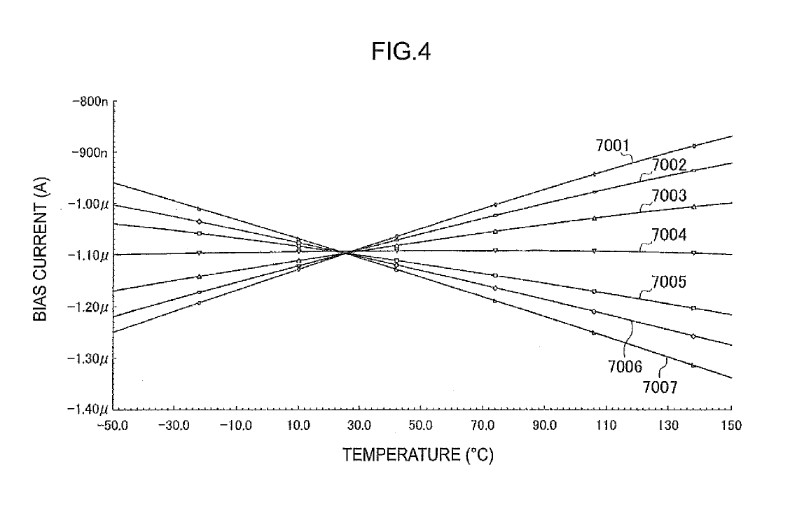

FIG. 4 is a graph illustrating the temperature dependency of the bias current. As explained above, the bias current Ib output from the voltage-current conversion circuit 30 is equivalent to the output current Iout obtained by converting the output voltage Vout. As illustrated in FIG. 4, the bias current Ib output from the voltage-current conversion circuit 30 fluctuates widely according to temperature unless adjusted for temperature dependency. The temperature dependency of the bias current Ib changes from line 7001 to line 7007 as the temperature dependency of the output voltage Vout illustrated in FIG. 3 changes from line 6001 to line 6007. The bias current Ib is substantially constant irrespective of temperature on line 7004.

However, the temperature dependency of the bias current Ib does not only change according to the temperature dependency of the output voltage Vout, it also changes according to the temperature dependency of the output voltage Vout and according to manufacturing variability in the variable resistor RV1. The temperature dependency of the output current Tout is accordingly adjusted by changing the resistance of the variable resistor RV1 so as to obtain the desired bias current Ib at a predetermined temperature. For example, as shown in FIG. 4, the bias current Ib can be obtained adjusted to be 1.1 μA at 25° C.

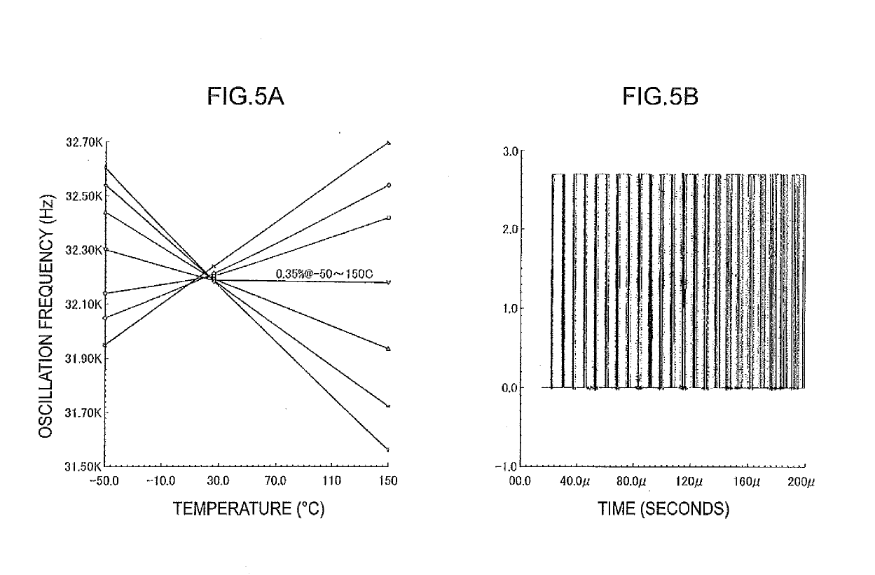

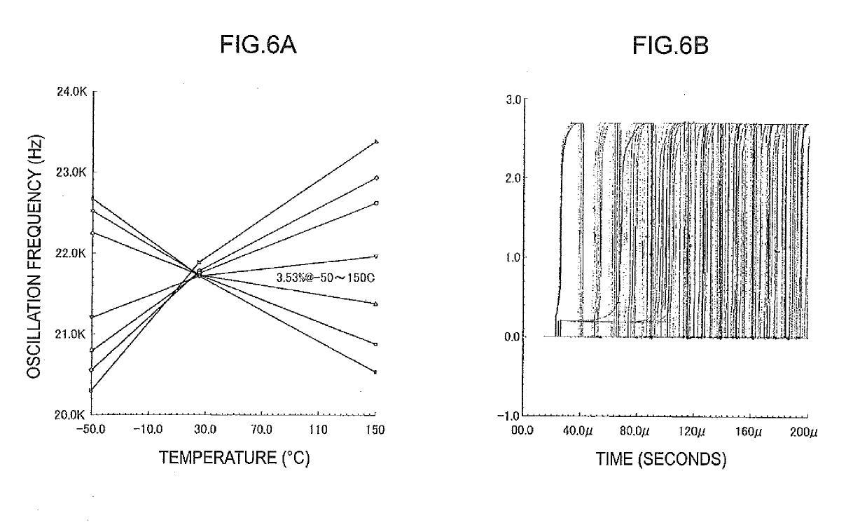

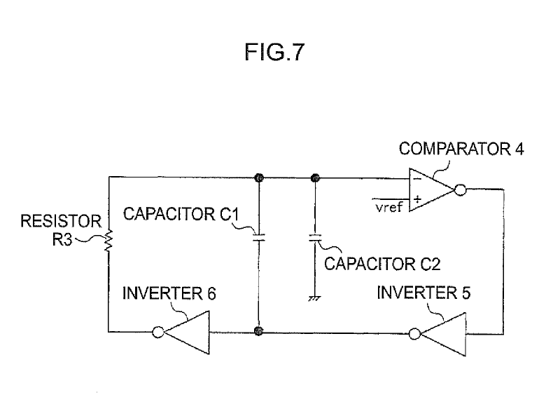

FIG. 5A illustrates the temperature dependency of oscillation frequency when a 100 nA bias current flows, and FIG. 5B illustrates the oscillation waveform therefor. FIG. 6A illustrates the temperature dependency of the oscillation frequency when a 10 nA bias current flows, and FIG. 6B illustrates the oscillation waveform therefor. As shown in FIG. 5A and FIG. 6A, the temperature dependency of the oscillation frequency of the CR oscillation circuit 40 changes according to the temperature dependency of the output voltage Vout shown from line 6001 to line 6007 of FIG. 3.

As shown in FIG. 5A, the temperature dependency of the oscillation frequency can be adjusted such that the error in oscillation frequency is 0.35% with the bias current Ib at 100 nA over the temperature range of −50° C. to 150° C. As shown in FIG. 6A, the bias current Ib can be reduced to 10 nA if the error of the oscillation frequency is increased to 3.5% over the temperature range of −50° C. to 150° C. Since the bias current Ib can be suppressed there are advantages for example in halt mode where oscillation frequency precision is not required but low current consumption is demanded.

It can be seen that the temperature dependency of the oscillation frequency is decreased by increasing the amperage of the bias current Ib. Namely, fluctuations according to temperature in the oscillation frequency can be suppressed. This is thought to be because the impact from the leak amperage of the PMOS transistor MP 2 and impact from parasitic resistance and parasitic capacitance is reduced by increasing the amperage of the bias current Ib.

The impact from manufacturing variability in the PMOS transistor MP 2 can be reduced in the region where the amperage of the bias current Ib is large, enabling high-precision oscillation to be obtained. Therefore, the resistance of the variable resistor RV1 is set low to increase the amperage of the bias current Ib if high-precision oscillation is required during CPU operation. On the other hand, the current consumption of the oscillation circuit can be suppressed if precision is not required, such as in standby or halt modes, by raising the resistance of the variable resistor RV1 to decrease the amperage of the bias current Ib.

As explained above, in the present exemplary embodiment, the temperature dependency of the oscillation frequency is adjusted by adjusting the temperature dependency of the output voltage Vout with the band-gap circuit 20 and adjusting the temperature dependency of the output current Iout and the bias current Ib with the voltage-current conversion circuit 30. In addition, the temperature dependency of the oscillation frequency is finally adjusted with the variable resistor RV2 of the CR oscillation circuit 40. The temperature dependency of oscillation frequency is significantly reduced by adjusting the temperature dependency in such stages, and a constant oscillation frequency can accordingly be obtained irrespective of temperature.

In the present exemplary embodiment, it is also possible to achieve high-precision oscillation with reduced temperature dependency of oscillation frequency if high-precision oscillation is required during CPU operation, and to also possible to reduce current consumption of the oscillation circuit if high-precision oscillation is not required in standby or halt modes. Namely, both high-precision oscillation and low current consumption oscillation can be achieved with a single oscillation circuit. A reduction in surface area of an integrated circuit can accordingly be achieved since there is no need to mount two or more such oscillation circuits thereon.

Configuration can be made with the variable resistor RV1 and the variable resistor RV2 being the same type of resistor, without the need to employ two types of resistor with different temperature dependencies from each other. This enables a mask to be omitted in the fabrication process. The surface area of the integrated circuit can also be reduced since there is no need for the number of trimmings combinations when using two types of resistor.

In the above exemplary embodiment, the temperature dependency of the output current Iout is adjusted by the band-gap circuit 20 and the voltage-current conversion circuit 30. However, configuration may be made with the voltage-current conversion circuit 30 omitted by utilizing a band-gap circuit capable of adjusting the temperature dependency of the output current Tout. For example, a band-gap circuit can be constructed capable of adjusting the temperature dependency and amperage of the output current Iout by employing a resistor with positive temperature dependency.

In the above exemplary embodiment, the CR oscillation circuit 40 with the comparator COMP 1 as a comparator section is employed and the bias current Ib is supplied to the comparator COMP1. This “comparator section” is a section that operates so as to transition to an output inverting state according to an input state of a specific reference voltage (for example a threshold value corresponding to Vref of FIG. 1 and Vref), and corresponds to a comparator or inverter equipped with a current limiting function. A CR oscillation circuit with an inverter in place of a comparator can therefore be employed. When the CR oscillation circuit with an inverter is employed, a bias current source is inserted at the source side of the MOS transistor of the invertor.

In the above exemplary embodiment, the amperage adjustment is performed with the variable resistor RV1 and the variable resistor RV2, however configuration may be made so as to adjust the ratio of the currents flowing in the PMOS transistor MP 1 and the PMOS transistor MP 2 of the voltage-current conversion circuit 30.

The oscillation circuit explained in the above exemplary embodiment is merely an example thereof, and obviously various changes are possible according to circumstances within a range not departing from the spirit of the present invention.

What is claimed is:

1. An oscillation circuit comprising:
a band-gap circuit that outputs an output voltage adjusted for temperature dependency so as to give a constant output voltage independent of temperature;
a voltage-current conversion circuit including a first variable resistor, the voltage-current conversion circuit converting an output voltage output from the band-gap circuit into an output current corresponding to the resistance of the first variable resistor and outputting a bias current based on the converted output current; and
a CR oscillation circuit including a second variable resistor, a capacitor and a comparator section, the CR oscillation circuit oscillating with an oscillation frequency based on the resistance of the second variable resistor and the capacitance value of the capacitor, and the CR oscillation circuit operating according to the amperage of the bias current the comparator section has input from the voltage-current conversion circuit.

2. The oscillation circuit of claim 1, wherein the resistance of the first variable resistor is set to a first set value such that the amperage of the output current obtained by the voltage-current conversion circuit is a predetermined amperage according to temperature such that the oscillation frequency is constant.

3. The oscillation circuit of claim 1, wherein the resistance of the second variable resistor is set such that the oscillation frequency is constant.

4. The oscillation circuit of claim 1, wherein the resistance of the first variable resistor is set to a first set value if high-precision oscillation is required, and the resistance of the first variable resistor is set to a second set value higher than the first set value if high-precision oscillation is not required.
